(19) United States
(12) Patent Application Publication
(10) Pub. No.: US 2026/0293370 A1
(43) Pub. Date: Sep. 24, 2026

(54) MICRO LED CHIP AND PREPARATION METHOD THEREOF

(71) Applicant: Beijing Zitiao Network Technology Co., Ltd., Beijing (CN)

(72) Inventors: Zhen HUANG, Beijing (CN); Chenggong WANG, Beijing (CN); Duo LI, Beijing (CN); Xiaokai LI, Beijing (CN)

(21) Appl. No.: 19/476,928

(22) PCT Filed: May 29, 2024
(86) PCT No.: PCT/CN2024/096022

§ 371 Date: Oct. 20, 2025

(30) Foreign Application Priority Data
Jun. 28, 2023 (CN) 202310777777.8

(51) Int. Cl. H10H 20/01; H10H 20/812; H10H 20/813; H10H 20/832; H10H 20/84; H10H 20/856

(52) U.S. Cl. CPC H10H 20/017; H10H 20/0137; H10H 20/032; H10H 20/034; H10H 20/0363; H10H 20/812; H10H 20/8132; H10H 20/835; H10H 20/84; H10H 20/856

(57) ABSTRACT

A method for preparing the Micro-LED chip includes: forming a blue pixel column, a green pixel column, and a red pixel column, where forming the pixel columns includes: epitaxially growing a plurality of first n-type doped GaN layers arranged at intervals on the side of the buffer layer; growing a first barrier layer on a surface of the first n-type doped GaN layers; growing a quantum well structure layer on a surface of the first barrier layer; sequentially growing a blue quantum well light-emitting layer, a green quantum well light-emitting layer, and a red quantum well light-emitting layer on a surface of the quantum well structure layer; etching and removing the red quantum well light-emitting layer and the green quantum well light-emitting layer used for forming the blue pixel column; and etching and removing the red quantum well light-emitting layer used for forming the green pixel column.

### CROSS-REFERENCE TO RELATED APPLICATION(S)

The present application claims priority to Chinese Patent Application No. 202310777777.8, filed on Jun. 28, 2023, and entitled “MICRO LED CHIP AND PREPARATION METHOD THEREOF”, which is hereby incorporated by reference in its entirety.

### TECHNICAL FIELD

The present disclosure relates to the technical field of chips, in particular to a micro LED chip and a preparation method thereof.

### BACKGROUND

Compared with LCD and OLED, a miniaturized light emitting diode (Micro-LED) adopts a self-luminous mechanism and has great advantages in terms of inherent brightness and device stability, and is a strong competitor for realizing AR technology.

### SUMMARY

An object of the present disclosure is to provide a method for preparing a Micro-LED chip.

In one aspect of the present disclosure, the present disclosure provides a method for preparing a Micro-LED chip. According to an embodiment of the present disclosure, the method for preparing a Micro-LED chip includes: providing a substrate; forming a buffer layer on a surface of the substrate; and forming a plurality of pixel columns arranged at intervals on a side of the buffer layer away from the substrate, where the pixel columns include a blue pixel column, a green pixel column, and a red pixel column, and a method for forming the pixel columns includes: epitaxially growing a plurality of first n-type doped GaN layers arranged at intervals on the side of the buffer layer away from the substrate; growing a first barrier layer on a surface of the first n-type doped GaN layer away from the substrate; growing a quantum well structure layer on a surface of the first barrier layer away from the substrate; sequentially growing a blue quantum well light-emitting layer, a green quantum well light-emitting layer, and a red quantum well light-emitting layer on a surface of the quantum well structure layer away from the substrate to obtain the red pixel column; etching and removing the red quantum well light-emitting layer and the green quantum well light-emitting layer for forming the blue pixel column to obtain the blue pixel column; and etching and removing the red quantum well light-emitting layer for forming the green pixel column to obtain the green pixel column. In this way, by epitaxially growing the RGB Micro LED pixel columns, on one hand, monolithic integration can be realized to achieve full color; on the other hand, damage to sidewalls of the pixel columns caused by etching in a chip preparation process can be reduced to a certain extent, thereby improving light-emitting performance of the chip.

According to an embodiment of the present disclosure, the method for preparing a Micro-LED chip further includes: depositing a first isolation layer in gaps between the blue pixel column, the green pixel column, and the red pixel column, wherein the first isolation layer covers surfaces of the blue pixel column, the green pixel column, and the red pixel column; etching and removing parts of the first isolation layer which are on and orthogonally correspond to the surfaces of the blue pixel column, the green pixel column, and the red pixel column to expose the surfaces of the blue pixel column, the green pixel column, and the red pixel column; growing a protection layer, an electron blocking layer, and a first partial hole injection layer on the surfaces of the blue pixel column, the green pixel column, and the red pixel column, so that a surface of the first partial hole injection layer away from the substrate is flush with a surface of the first isolation layer away from the substrate; growing a second partial hole injection layer on the surface of the first partial hole injection layer away from the substrate and the surface of the first isolation layer away from the substrate; and depositing and forming an ohmic contact layer on a surface of the second partial hole injection layer away from the substrate.

According to an embodiment of the present disclosure, the method for preparing a Micro-LED chip further includes: S1: growing a first undoped GaN layer on a surface of the buffer layer away from the substrate, wherein a thickness of the first undoped GaN layer is 0.5 μm-1 μm; S2: forming a first inorganic layer on a surface of the first undoped GaN layer away from the substrate, wherein the first inorganic layer has a plurality of openings arranged at intervals, and a thickness of the first inorganic layer is 10 nm-30 nm; S3: growing a second undoped GaN layer on a surface of the first undoped GaN layer not covered by the first inorganic layer, wherein the second undoped GaN layer covers a surface of the first inorganic layer, and wherein a thickness of the second undoped GaN layer is 0.5 μm-1 μm; and S4: repeating steps S2 and S3 until a total thickness of the undoped GaN layers is 3.5 μm-4 μm, wherein an orthographic projection of the pixel columns on the substrate is located within an orthographic projection of the first inorganic layer on the substrate.

According to an embodiment of the present disclosure, the method for preparing a Micro-LED chip further includes: etching a first groove and a second groove on a surface of the undoped GaN layer, wherein an orthographic projection of the first groove on the substrate overlaps with an orthographic projection of the green pixel column on the substrate, wherein an orthographic projection of the second groove on the substrate overlaps with an orthographic projection of the red pixel column on the substrate, and a depth of the second groove is greater than a depth of the first groove; and depositing a second inorganic layer on a surface of the undoped GaN layer away from the substrate, wherein the second inorganic layer has a first through hole, a second through hole, and a third through hole penetrating through the second inorganic layer, the first through hole exposes the first groove, the second through hole exposes the second groove, and the third through hole exposes a predetermined region of the undoped GaN layer, wherein an orthographic projection of the predetermined region on the substrate overlaps with an orthographic projection of the blue pixel column on the substrate, wherein the blue pixel column is disposed in the third through hole, the green pixel column is disposed in the first through hole, and the red pixel column is disposed in the second through hole.

According to an embodiment of the present disclosure, the depth of the first groove is 28 nm-145 nm, and the depth of the second groove is 50 nm-300 nm, and optionally, the thickness of the second inorganic layer is 100 nm-300 nm.

According to an embodiment of the present disclosure, a step of growing the first n-type doped GaN layer comprises sequentially growing a n-type heavily doped GaN layer and a n-type lightly doped GaN layer, a doping concentration of the n-type heavily doped GaN layer is 5×10¹⁸ cm⁻³-1×10¹⁹ cm⁻³, a thickness of the n-type heavily doped GaN layer is 1.5 μm-2.5 μm, a doping concentration of the n-type lightly doped GaN layer is 3×10¹⁷ cm⁻³-6×10¹⁷ cm⁻³, and a thickness of the n-type lightly doped GaN layer is 0.3 μm-0.5 μm; the first barrier layer is undoped GaN, and a thickness of the first barrier layer is 20 nm-60 nm; a step of growing the quantum well structure layer comprises sequentially growing a first quantum well structure layer and a second quantum well structure layer, the first quantum well structure layer comprises an InₓGa₁₋ₓN well layer and a GaN barrier layer which are arranged in a stacked manner, x is 0.01-0.03, a thickness of the InₓGa₁₋ₓN well layer is 2.5 nm-3.5 nm, and a thickness of the GaN barrier layer is 5 nm-15 nm; and the second quantum well structure layer comprises an In_{y}Ga_{1-y}N well layer and a second n-type doped GaN barrier layer which are arranged in a stacked manner, y is 0.03-0.05, a thickness of the In_{y}Ga_{1-y}N well layer is 2.5 nm-3.5 nm, a thickness of the second n-type doped GaN barrier layer is 5 nm-15 nm, and a doping concentration of the second n-type doped GaN barrier layer is 1×10¹⁷ cm⁻³-5×10¹⁷ cm⁻³.

According to an embodiment of the present disclosure, the blue quantum well light-emitting layer comprises a first undoped GaN film layer, an InₐGa₁₋ₐN well layer, a second undoped GaN film layer, and an In_{b}Ga_{1-b}N barrier layer which are arranged in a stacked manner, wherein a is 0.18-0.21, and b is 0.01-0.05; the green quantum well light-emitting layer comprises a third undoped GaN film layer, an In_{c}Ga_{1-c}N well layer, a fourth undoped GaN film layer, a first n-type doped GaN barrier layer, a fifth undoped GaN film layer, an In_{d}Ga_{1-d}N well layer, a sixth undoped GaN film layer, and a second n-type doped GaN barrier layer which are arranged in a stacked manner, wherein c is 0.24-0.25, and d is 0.25-0.28; and the red quantum well light-emitting layer comprises a seventh undoped GaN film layer, an InₑGa₁₋ₑN well layer, an eighth undoped GaN film layer, a p-type doped GaN barrier layer, and an AlₕGa₁₋ₕN layer which are arranged in a stacked manner, wherein e is 0.35-0.38, and h is 0.10-0.30.

According to an embodiment of the present disclosure, the blue quantum well light-emitting layer, the green quantum well light-emitting layer and the red quantum well light-emitting layer further satisfy at least one of the following conditions: thicknesses of the first undoped GaN film layer to the eighth undoped GaN film layer are 12 nm-8 nm, respectively; a thickness of the InₐGa₁₋ₐN well layer is 2.5 nm-3.5 nm, and a thickness of the In_{b}Ga_{1-b}N barrier layer is 5 nm-15 nm; a thickness of the In_{c}Ga_{1-c}N well layer is 2.5 nm-3.5 nm, a thickness of the first n-type doped GaN barrier layer is 5 nm-15 nm, a doping concentration of the first n-type doped GaN barrier layer is 1×10¹⁷ cm⁻³-5×10¹⁷ cm⁻³, a thickness of the In_{d}Ga_{1-d}N well layer is 2.5 nm-3.5 nm, a thickness of the second n-type doped GaN barrier layer is 5 nm-15 nm, and a doping concentration of the second n-type doped GaN barrier layer is 1×10¹⁷ cm⁻³-5×10¹⁷ cm⁻³, and a thickness of the InₑGa₁₋ₑN well layer is 2.5 nm-3.5 nm, a thickness of the p-type doped GaN barrier layer is 5 nm-15 nm, and a thickness of the AlₕGa₁₋ₕN layer is 1 nm-2 nm.

According to an embodiment of the present disclosure, a sum of thicknesses of the protection layer, the electron blocking layer, and the first partial hole injection layer is 120 nm-180 nm.

According to an embodiment of the present disclosure, the substrate is a sapphire substrate, and the buffer layer is an aluminum nitride layer; or the substrate is a silicon substrate, the buffer layer is an aluminum nitride layer and an aluminum gallium nitride layer, and the aluminum content in the aluminum gallium nitride layer decreases gradually in a direction away from the substrate; or the substrate is a n-type doped silicon carbide substrate, the buffer layer is an aluminum nitride layer and an aluminum gallium nitride layer, and the aluminum content in the aluminum gallium nitride layer decreases gradually in a direction away from the substrate.

According to an embodiment of the present disclosure, the substrate is a n-type doped silicon carbide substrate, the buffer layer is a n-type doped aluminum gallium nitride layer, and the pixel columns are directly formed on a surface of the buffer layer away from the substrate; or the substrate is a n-type doped gallium nitride substrate, the buffer layer is an aluminum nitride layer, and the pixel columns are directly formed on a surface of the buffer layer away from the substrate.

According to an embodiment of the present disclosure, the method for preparing a Micro-LED chip further includes: sequentially depositing and forming a first conductive film layer, a reflector, and a bonding metal layer on a surface of the ohmic contact layer away from the substrate; bonding a pixel driving circuit on a surface of the bonding metal layer away from the substrate; peeling the substrate; etching a layer structure between the pixel columns and the substrate and part of the n-type heavily doped GaN layer in the pixel columns by an etching method until a surface of the blue pixel column away from the first conductive film layer, a surface of the green pixel column away from the first conductive film layer, and a surface of the red pixel column away from the first conductive film layer are located in the same plane; removing the first isolation layer between the blue pixel column, the green pixel column, and the red pixel column; sequentially forming a sidewall passivation layer and a reflective film layer on the surfaces of the pixel columns; etching and removing part of the sidewall passivation layer, the reflective film layer, the second partial hole injection layer, the ohmic contact layer, and the first conductive film layer between different pixel columns to form an isolation groove; depositing and forming a second isolation layer in the isolation groove; removing at least part of the sidewall passivation layer and the reflective film layer on mesas of the pixel columns to expose a surface of the n-type heavily doped GaN layer; forming a second conductive film layer on the mesas of the pixel columns, on a sidewall of the reflective film layer, and on a surface of the second isolation layer; depositing a third isolation layer on a sidewall and a bottom wall of the second conductive film layer; and forming a highly reflective electrode in the third isolation layer, and the highly reflective electrode is disposed in contact with the second conductive film layer.

In another aspect of the present disclosure, the present disclosure provides a Micro LED chip. According to an embodiment of the present disclosure, the Micro LED chip is prepared by using the above method.

### BRIEF DESCRIPTION OF THE DRAWINGS

The above and/or additional aspects and advantages of the present disclosure will become apparent and easy to understand from the description of the embodiments in conjunction with the following drawings, in which:

FIG. 1 is a flowchart of preparing a partial structure of a Micro-LED chip in one embodiment of the present disclosure;

FIG. 2 is a flowchart of preparing a partial structure of a Micro-LED chip in another embodiment of the present disclosure;

FIG. 3 is a flowchart of preparing a partial structure of a Micro-LED chip in yet another embodiment of the present disclosure;

FIG. 4 is a structural diagram of a blue quantum well light-emitting layer in another embodiment of the present disclosure;

FIG. 5 is a structural diagram of a green quantum well light-emitting layer in another embodiment of the present disclosure;

FIG. 6 is a structural diagram of a red quantum well light-emitting layer in another embodiment of the present disclosure;

FIG. 7 is a flowchart of preparing a partial structure of a Micro-LED chip in yet another embodiment of the present disclosure;

FIG. 8 is a flowchart of preparing a partial structure of a Micro-LED chip in yet another embodiment of the present disclosure;

FIG. 9 is a flowchart of preparing a partial structure of a Micro-LED chip in yet another embodiment of the present disclosure;

FIG. 10 is a flowchart of preparing a partial structure of a Micro-LED chip in yet another embodiment of the present disclosure; and

FIG. 11 is a flowchart of preparing a partial structure of a Micro-LED chip in yet another embodiment of the present disclosure.

### DETAILED DESCRIPTION OF EMBODIMENTS

The solutions of the present disclosure will be explained below in conjunction with the embodiments. Those skilled in the art will understand that the following embodiments are only used to illustrate the present disclosure, and should not be construed as limiting the scope of the present disclosure. If a specific technique or condition is not specified in the embodiment, the technique or condition described in the literature in the art or the product specification is followed. The present disclosure will be described below with reference to specific embodiments. It should be noted that these embodiments are only descriptive, and do not limit the present disclosure in any way.

The electro-optical conversion efficiency of red Micro-LEDs based on AlGaInP material decreases significantly at a small size (<10 μm), which restricts the development of full-color Micro-LED display technology.

In the process of fabricating a red Micro-LED array, the AlGaInP material system has a high surface recombination velocity and a long minority carrier diffusion length, thus small-size etching and cutting will lead to serious carrier leakage and a decrease in quantum efficiency of more than 90% at the expected Micro-LED size. Secondly, when integrating three primary color dies in full-color Micro-LED display, the current mainstream blue and green InGaN-based Micro-LED chips cannot be directly integrated with AlGaInP red light chip due to different material systems, resulting in a complex circuit structure, a significant reduction in transfer yield, and a large amount of additional costs.

The method for preparing a Micro-LED chip of the present disclosure can achieve monolithic integration and full color, or can reduce damage to sidewalls of pixel columns caused by etching in a chip preparation process to a certain extent. The Micro LED chip of the present disclosure can achieve better monolithic integration and full color, and can further improve the light-emitting performance of the chip. Those skilled in the art can understand that the Micro LED chip of the present disclosure has all the features and advantages of the above-mentioned method for preparing a Micro LED chip, which will not be repeated here.

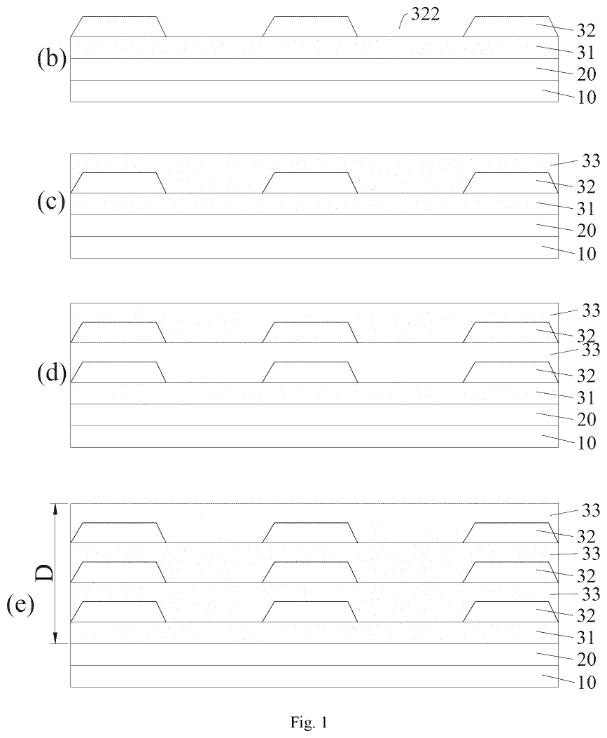

In one aspect of the present disclosure, the present disclosure provides a method for preparing a Micro-LED chip. According to an embodiment of the present disclosure, referring to FIG. 1 to FIG. 11, the method for preparing a Micro-LED chip includes:

S100: providing a substrate 10.

The specific type of the substrate may be a sapphire substrate, a silicon substrate, a n-type doped silicon carbide substrate, or a n-type doped gallium nitride substrate, and those skilled in the art can flexibly select a suitable substrate type according to a specific structure type of the Micro-LED chip.

S200: forming a buffer layer 20 on a surface of the substrate 10. The buffer layer may be deposited by physical vapor deposition (PVD), and a thickness of the buffer layer is 10 nm-100 nm.

Those skilled in the art can select a suitable buffer layer structure according to a specific type of the substrate. In some embodiments, the substrate 10 is a sapphire substrate, the buffer layer 20 is an aluminum nitride layer, and a thickness of the buffer layer is 10 nm-100 nm. In other embodiments, the substrate 10 is a silicon substrate, the buffer layer 20 is an aluminum nitride layer and an aluminum gallium nitride layer, and an aluminum content in the aluminum gallium nitride layer gradually decreases in a direction away from the substrate 10. In other embodiments, the substrate 10 is a n-type doped silicon carbide substrate, the buffer layer 20 is an aluminum nitride layer and an aluminum gallium nitride layer, and an aluminum content in the aluminum gallium nitride layer gradually decreases in a direction away from the substrate 10. In other embodiments, the substrate 10 is a n-type doped silicon carbide substrate, and the buffer layer 20 is a n-type doped aluminum gallium nitride layer. In yet other embodiments, the substrate is a n-type doped gallium nitride substrate, which is a directly grown n-GaN layer.

According to some embodiments of the present disclosure, when the substrate 10 is a n-type doped silicon carbide substrate and the buffer layer 20 is a n-type doped aluminum gallium nitride layer (epitaxial wafer (Epi-Wafer) with a vertical structure), and when the substrate is a n-type doped gallium nitride substrate and the buffer layer is an aluminum nitride layer, subsequent pixel columns may be directly formed on a surface of the buffer layer.

According to other embodiments of the present disclosure, when the substrate 10 is a sapphire substrate and the buffer layer 20 is an aluminum nitride layer, when the substrate 10 is a silicon substrate and the buffer layer 20 is an aluminum nitride layer and an aluminum gallium nitride layer and an aluminum content in the aluminum gallium nitride layer gradually decreases in a direction away from the substrate 10, and when the substrate 10 is a n-type doped silicon carbide substrate and the buffer layer 20 is an aluminum nitride layer and an aluminum gallium nitride layer and an aluminum content in the aluminum gallium nitride layer gradually decreases in a direction away from the substrate 10 (epitaxial wafer (Epi-Wafer) with a horizontal structure), referring to FIG. 1, the method for preparing a Micro-LED chip further includes:

S1: growing a first undoped GaN layer 31 on a surface of the buffer layer 10 away from the substrate 10, where a thickness of the first undoped GaN layer 31 is 0.5 μm-1 μm (for example, 0.5 μm, 0.6 μm, 0.7 μm, 0.8 μm, 0.9 μm, or 1.0 μm). Specifically, it can be obtained by epitaxial growth using MOCVD (Metal Organic Chemical Vapor Deposition, which is a high-purity chemical vapor deposition technology for preparing semiconductor materials and devices).

S2: forming a first inorganic layer 32 on a surface of the first undoped GaN layer 31 away from the substrate 10, where the first inorganic layer 32 has a plurality of openings 322 arranged at intervals, and a thickness of the first inorganic layer 32 is 10 nm-30 nm (for example, 10 nm, 12 nm, 15 nm, 18 nm, 20 nm, 23 nm, 25 nm, 28 nm, or 30 nm), as shown in (a) and (b) of FIG. 1. By depositing the first inorganic layer 32, dislocation density in the first undoped GaN layer 31 material can be reduced. The first inorganic layer 32 may be formed by the following method: depositing an inorganic film layer 321 by plasma enhanced chemical vapor deposition (PECVD), and then etching the inorganic film layer into the first inorganic layer 32 having a strip structure or a mesh structure by processes such as coating a photoresist, exposure, development, etching, photoresist stripping, and cleaning. The size and shape of the openings in the first inorganic layer 32 need to be set according to the size and shape of the pixels. In addition, the first inorganic layer with the above thickness can not only effectively reduce the dislocation density in the first undoped GaN layer 31 material, but also avoid an excessive thickness of the first inorganic layer, thereby causing material waste. The material of the first inorganic layer may be silicon nitride, silicon oxide, or the like.

S3: growing a second undoped GaN layer 33 on a surface of the first undoped GaN layer 31 not covered by the first inorganic layer 32, and the second undoped GaN layer 33 covers a surface of the first inorganic layer 32, as shown in (c) of FIG. 1, where a thickness of the second undoped GaN layer 33 is 0.5 μm-1 μm (for example, 0.5 μm, 0.6 μm, 0.7 μm, 0.8 μm, 0.9 μm, or 1.0 μm). Specifically, the second undoped GaN layer 33 may be obtained by epitaxial growth using MOCVD. Since the undoped GaN material cannot be directly grown on the surface of the inorganic layer, nucleation continues firstly on the surface of the first undoped GaN layer 31 exposed by the first inorganic layer, and undoped GaN is gradually grown laterally by epitaxy after the thickness exceeds 10 nm-30 nm. At this time, the first inorganic layer 32 can better act as a mask to prevent further extension of dislocations.

S4: repeating steps S2 and S3 at least once until a total thickness of the undoped GaN layers (all the undoped GaN layers including the first undoped GaN layer 31, the second undoped GaN layer 33, and the second undoped GaN layer(s) 33 repeatedly grown in the step S4) is 3.5 μm-4 μm, where an orthographic projection of subsequently prepared pixel columns on the substrate is located within an orthographic projection of the first inorganic layer 32 on the substrate, as shown in (d) of FIG. 1. Through the above steps, the first inorganic layer 32 is formed multiple times, which can well reduce further extension of dislocations in the undoped GaN layer corresponding to the pixel columns, so that the density of threading dislocations in this region is low, that is, non-radiative recombination centers are reduced, which is conducive to obtaining a high-performance Micro LED pixel array and improving the light-emitting performance of the Micro LED chip to a certain extent.

Further, as shown in FIG. 1, orthographic projections of the first inorganic layers 32 of different layers on the substrate basically overlap. In this way, in the steps S1 to S4, the same mask may be used when preparing the first inorganic layers 32 of different layers, so as to save the number of masks and reduce the preparation cost. The first inorganic layers of different layers may be the same or different, as long as they are in a range of 10 nm-30 nm.

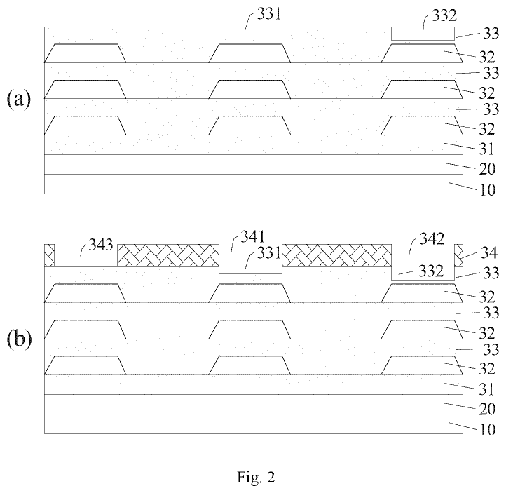

According to an embodiment of the present disclosure, in order to grow pixel columns subsequently, referring to FIG. 2, the method for preparing a Micro-LED chip further includes:

S5: etching a first groove 331 and a second groove 332 on a surface of the undoped GaN layer (that is, the second undoped GaN layer 33 at the top layer in the step S4), where an orthographic projection of the first groove 331 on the substrate 10 overlaps with an orthographic projection of the green pixel column on the substrate, an orthographic projection of the second groove 332 on the substrate 10 overlaps with an orthographic projection of the red pixel column on the substrate, and a depth of the second groove 332 is greater than a depth of the first groove 331.

The first groove 331 and the second groove 332 may be etched by using another mask and processes such as coating a photoresist, exposure, development, etching, photoresist stripping, and cleaning. In addition, a depth of the first groove is 28 nm-145 nm (for example, 28 nm, 35 nm, 40 nm, 50 nm, 60 nm, 70 nm, 80 nm, 90 nm, 100 nm, 110 nm, 120 nm, 130 nm, or 145 nm), and a depth of the second groove is 50 nm-300 nm (for example, 50 nm, 60 nm, 70 nm, 80 nm, 90 nm, 100 nm, 110 nm, 120 nm, 130 nm, 150 nm, 180 nm, 200 nm, 230 nm, 250 nm, 280 nm, or 300 nm).

S6: depositing a second inorganic layer 34 on a surface of the undoped GaN layer away from the substrate 10, where the second inorganic layer 34 has a first through hole 341, a second through hole 342, and a third through hole 343 penetrating through the second inorganic layer 34, the first through hole 341 exposes the first groove 331, the second through hole 342 exposes the second groove 332, and the third through hole 343 exposes a predetermined region of the undoped GaN layer (that is, the second undoped GaN layer 33 at the top layer in the step S4), where an orthographic projection of the predetermined region on the substrate 10 overlaps with an orthographic projection of the blue pixel column on the substrate, the blue pixel column is disposed in the third through hole 343, the green pixel column is disposed in the first through hole 341, and the red pixel column is disposed in the second through hole 342, that is, the first through hole 341, the second through hole 342, and the third through hole 343 expose the growth surfaces of the green pixel column, the red pixel column, and the blue pixel column, respectively. A thickness of the second inorganic layer 34 is 100 nm-300 nm, for example, 100 nm, 130 nm, 150 nm, 180 nm, 200 nm, 230 nm, 250 nm, 280 nm, or 300 nm; and a material of the second inorganic layer may be silicon nitride, silicon oxide, or the like.

In some examples, the method for forming the second inorganic layer 34 may include: depositing an inorganic thin film on a surface of the undoped GaN layer away from the substrate 10 and in the first groove and the second groove, and then etching the inorganic thin film to obtain the patterned second inorganic layer 34 by using another mask and processes such as exposure, development, etching, photoresist stripping, and cleaning.

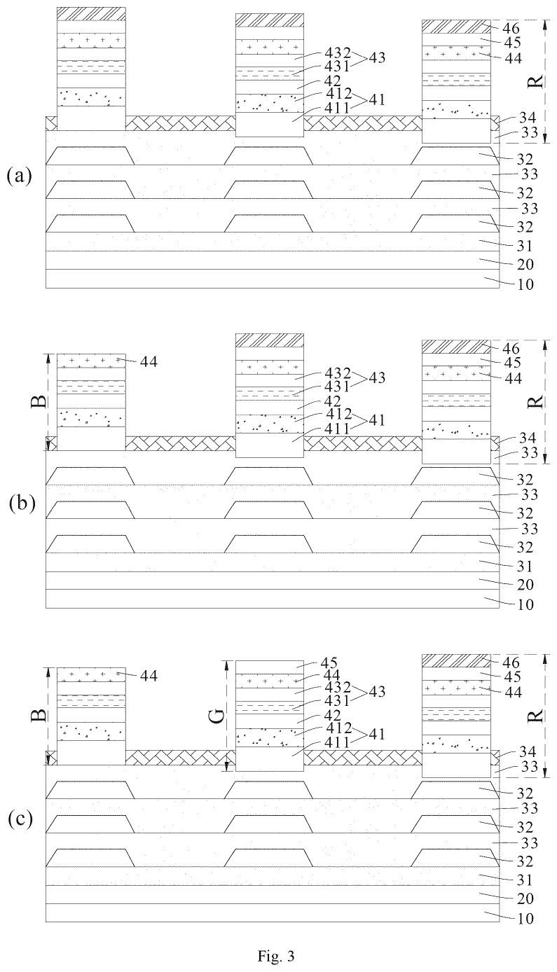

S300: referring to FIG. 3, forming a plurality of pixel columns arranged at intervals on a side of the buffer layer 20 away from the substrate (in FIG. 3, growing the blue pixel column, the green pixel column, and the red pixel column in the predetermined region, the first groove, and the second groove, respectively), where the pixel columns include a blue pixel column (or a blue light pixel column) B, a green pixel column (or a green light pixel column) G, and a red pixel column (or a red light pixel column) R, and the method for forming the pixel columns includes:

S310: epitaxially growing a plurality of first n-type doped GaN layers 41 arranged at intervals on a side of the buffer layer 20 away from the substrate (in FIG. 3, growing a plurality of first n-type doped GaN layers 41 arranged at intervals on surfaces of the undoped GaN layer exposed in the predetermined region, the first groove, and the second groove), referring to FIG. 3.

In some examples, the step of growing the first n-type doped GaN layer 41 includes sequentially growing a n-type heavily doped GaN layer 411 and a n-type lightly doped GaN layer 412, where the n-type heavily doped GaN layer 411 may be grown by metal organic chemical vapor deposition (MOCVD) at a growth temperature of 1040° C. to 1060° C., SiH₄ is used as the n-type dopant, a doping concentration of the n-type heavily doped GaN layer 411 is 5×10¹⁸ cm⁻³-1×10¹⁹ cm⁻³, and a thickness of the n-type heavily doped GaN layer 411 is 1.5 μm-2.5 μm; and the n-type lightly doped GaN layer 412 may be grown by metal organic chemical vapor deposition (MOCVD) at a growth temperature of 1040° C. to 1060° C., SiH₄ is used as the n-type dopant, a doping concentration of the n-type lightly doped GaN layer 412 is 3×10¹⁷ cm⁻³-6×10¹⁷ cm⁻³, and a thickness of the n-type lightly doped GaN layer 412 is 0.3 μm-0.5 μm.

S320: growing a first barrier layer 42 on a surface of the first n-type doped GaN layer 41 away from the substrate, referring to FIG. 3. A thickness of the first barrier layer 42 is 20 nm-60 nm, and a material of the first barrier layer 42 is undoped GaN.

S330: growing a quantum well structure layer 43 on a surface of the first barrier layer 42 away from the substrate 10, referring to FIG. 3.

In some embodiments of the present disclosure, the step of growing the quantum well structure layer 43 includes sequentially growing a first quantum well structure layer 431 and a second quantum well structure layer 432, where the first quantum well structure layer 431 is grown for 3 to 5 cycles, the first quantum well structure layer 431 includes an InₓGa₁₋ₓN well layer (or an InₓGa₁₋ₓN potential well layer) and a GaN barrier layer (or a GaN potential barrier layer) which are arranged in a stacked manner, x is 0.01-0.03, that is, a component of In in the InₓGa₁₋ₓN well layer is 1%-3%, the InₓGa₁₋ₓN well layer is disposed close to the first barrier layer 42, the GaN barrier layer is disposed away from the first barrier layer 42, a thickness of the InₓGa₁₋ₓN well layer is 2.5 nm-3.5 nm, and a thickness of the GaN barrier layer is 5 nm-15 nm. The second quantum well structure layer includes an In_{y}Ga_{1-y}N well layer and a second n-type doped GaN barrier layer which are arranged in a stacked manner, y is 0.03-0.05, that is, a component of In in the In_{y}Ga_{1-y}N well layer is 3%-5%, the In_{y}Ga_{1-y}N well layer is disposed close to the first barrier layer 42, the second n-type doped GaN barrier layer is disposed away from the first barrier layer 42, a thickness of the In_{y}Ga_{1-y}N well layer is 2.5 nm-3.5 nm, a thickness of the second n-type doped GaN barrier layer is 5 nm-15 nm, and a doping concentration of the second n-type doped GaN barrier layer is 1×10¹⁷ cm⁻³-5×10¹⁷ cm⁻³.

In the process of growing the first quantum well structure layer 431, an undoped GaN layer is pre-grown before the InₓGa₁₋ₓN well layer is grown, and an undoped GaN layer is pre-grown before the GaN layer is grown. Thicknesses of the two undoped GaN layers are 1 μm-5 μm, and a growth temperature is the same as that of the InₓGa₁₋ₓN well layer, which is 1040-1060° C.

S340: sequentially growing a blue quantum well light-emitting layer 44, a green quantum well light-emitting layer 45, and a red quantum well light-emitting layer 46 on a surface of the quantum well structure layer 43 away from the substrate 10 to obtain the red pixel column R, referring to (a) in FIG. 3. A light-emitting wavelength of the blue quantum well light-emitting layer is 455 nm-465 nm, a light-emitting wavelength of the green quantum well light-emitting layer is 520 nm-535 nm, and a light-emitting wavelength of the red quantum well light-emitting layer is 620 nm-635 nm.

According to an embodiment of the present disclosure, the subsequent steps S350 and S360 are in an etching stage (hydrogen atmosphere), and the blue quantum well light-emitting layer 44, the green quantum well light-emitting layer 45, and the red quantum well light-emitting layer 46 formed in the step S340 are performed in a nitrogen atmosphere. Since there is a serious etching phenomenon when the nitrogen film-forming atmosphere is switched to the hydrogen atmosphere, a 30 nm-60 nm thick protection layer (which may be made of undoped GaN) may be pre-formed before the product obtained in the step S340 is removed from the nitrogen atmosphere, to prevent the formed blue quantum well light-emitting layer 44, green quantum well light-emitting layer 45, and red quantum well light-emitting layer 46 from being damaged.

S350: etching and removing the red quantum well light-emitting layer 46 and the green quantum well light-emitting layer 45 used to form the blue pixel column B to obtain the blue pixel column B, referring to (b) in FIG. 3.

S360: etching and removing the red quantum well light-emitting layer 46 used to form the green pixel column G to obtain the green pixel column G, referring to (c) in FIG. 3.

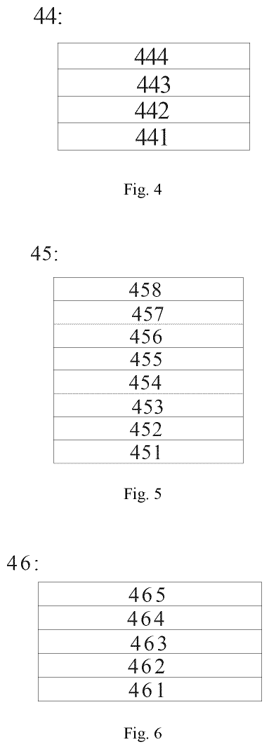

In some embodiments of the present disclosure, referring to FIG. 4, the blue quantum well light-emitting layer 44 includes a first undoped GaN film layer 441, an InₐGa₁₋ₐN well layer 442, a second undoped GaN film layer 443, and an In_{b}Ga_{1-b}N barrier layer 444 which are arranged in a stacked manner, where a is 0.18-0.21, and b is 0.01-0.05, that is, a component of In in the InₐGa₁₋ₐN well layer 4812 is 18%-21%, and a component of In in the In_{b}Ga_{1-b}N barrier layer 4814 is 1%-5%. The blue quantum well light-emitting layer 44 has a high indium content. Growing the first undoped GaN film layer 441 before growing the InₐGa₁₋ₐN well layer 442 can effectively improve the surface flatness of the film layer, improve the growth quality of the InₐGa₁₋ₐN well layer 442, and be beneficial to the improvement of the light-emitting brightness of the device. Growing the second undoped GaN film layer 443 before growing the In_{b}Ga_{1-b}N barrier layer 444 can prevent the precipitation of In in the InₐGa₁₋ₐN well layer, which is beneficial to the improvement of the light-emitting brightness of the device. The thicknesses of the first undoped GaN film layer 441 and the second undoped GaN film layer 443 are 1 nm-8 nm, respectively. The growth temperature of the first undoped GaN film layer 441 is the same as that of the InₐGa₁₋ₐN well layer 442, and the growth temperature of the second undoped GaN film layer 443 is the same as that of the In_{b}Ga_{1-b}N barrier layer 444, which can effectively alleviate the problem of wave shift (offset) under a large current injection. The thickness of the InₐGa₁₋ₐN well layer is 2.5 nm-3.5 nm, and the thickness of the In_{b}Ga_{1-b}N barrier layer is 5 nm-15 nm. In this way, good light-emitting characteristics of the blue quantum well light-emitting layer 44 are ensured.

In some embodiments of the present disclosure, referring to FIG. 5, the green quantum well light-emitting layer 45 includes a third undoped GaN film layer 451, an In_{c}Ga_{1-c}N well layer 452, a fourth undoped GaN film layer 453, a first n-type doped GaN barrier layer 454, a fifth undoped GaN film layer 455, an In_{d}Ga_{1-d}N well layer 456, a sixth undoped GaN film layer 457, and a second n-type doped GaN barrier layer 458 which are arranged in a stacked manner, where c is 0.24-0.25, and d is 0.25-0.28, that is, a component of In in the In_{c}Ga_{1-c}N 452 well layer is 24%-25%, and a component of In in the In_{d}Ga_{1-d}N well layer 456 is 25%-28%. The green quantum well light-emitting layer 45 has a high indium content. Growing the third undoped GaN film layer 451 before growing the In_{c}Ga_{1-c}N well layer 452 can effectively improve the surface flatness of the film layer, improve the growth quality of the In_{c}Ga_{1-c}N well layer 452, and be beneficial to the improvement of the light-emitting brightness of the device. Growing the fourth undoped GaN film layer 453 before growing the first n-type doped GaN barrier layer 454 can prevent the precipitation of In in the In_{c}Ga_{1-c}N well layer, which is beneficial to the improvement of the light-emitting brightness of the device. Growing the fifth undoped GaN film layer 455 before growing the In_{d}Ga_{1-d}N well layer 456 can effectively improve the surface flatness of the film layer, improve the growth quality of the In_{d}Ga_{1-d}N well layer 456, and be beneficial to the improvement of the light-emitting brightness of the device. Growing the sixth undoped GaN film layer 457 before growing the second n-type doped GaN barrier layer 458 can prevent the precipitation of In in the In_{d}Ga_{1-d}N well layer 456, which is beneficial to the improvement of the light-emitting brightness of the device.

The thicknesses of the third undoped GaN film layer to the sixth undoped GaN film layer are 2 nm-8 nm, respectively. The growth temperature of the third undoped GaN film layer 451 is the same as that of the In_{c}Ga_{1-c}N well layer 452. The growth temperature of the fourth undoped GaN film layer 453 is the same as that of the first n-type doped GaN barrier layer 454. The growth temperature of the fifth undoped GaN film layer 455 is the same as that of the In_{d}Ga_{1-d}N well layer 456. The growth temperature of the sixth undoped GaN film layer 457 is the same as that of the second n-type doped GaN barrier layer 458, which can effectively alleviate the problem of wave shift (offset) under a large current injection. The thickness of the In_{c}Ga_{1-c}N well layer is 2.5-3.5 nm, the thickness of the first n-type doped GaN barrier layer is 5 -15 nm, the doping concentration of the first n-type doped GaN barrier layer is 1×10¹⁷-5×10¹⁷ cm⁻³, the thickness of the In_{d}Ga_{1-d}N well layer is 2.5 nm-3.5 nm, the thickness of the second n-type doped GaN barrier layer is 5 nm-15 nm, and the doping concentration of the second n-type doped GaN barrier layer is 1×10¹⁷ cm⁻³-5×10¹⁷ cm⁻³. In this way, good light-emitting characteristics of the green quantum well light-emitting layer 45 are ensured.

In some embodiments of the present disclosure, referring to FIG. 6, the red quantum well light-emitting layer 46 includes a seventh undoped GaN film layer 461, an InₑGa₁₋ₑN well layer 462, an eighth undoped GaN film layer 463, a p-type doped GaN barrier layer 464, and an AlₕGa₁₋ₕN layer 465 which are arranged in a stacked manner, where e is 0.35-0.38, and h is 0.10-0.30, that is, a component of In in the InₑGa₁₋ₑN well layer 462 is 35%-38%, and a component of Al in the AlₕGa₁₋ₕN layer 465 is 10%-30%. The red quantum well light-emitting layer 46 has a high indium content. Growing the seventh undoped GaN film layer 461 before growing the InₑGa₁₋ₑN well layer 462 can effectively improve the surface flatness of the film layer, improve the growth quality of the InₑGa₁₋ₑN well layer 462, and be beneficial to the improvement of the light-emitting brightness of the device. Growing the eighth undoped GaN film layer 463 before growing the p-type doped GaN barrier layer 464 is beneficial to the improvement of the light-emitting brightness of the device.

The thicknesses of the seventh undoped GaN film layer and the eighth undoped GaN film layer are 2 nm-8 nm, respectively. The thickness of the InₑGa₁₋ₑN well layer is 2.5 nm-3.5 nm, the thickness of the p-type doped GaN barrier layer is 5 nm-15 nm, and the thickness of the AlₕGa₁₋ₕN layer is 1 nm-2 nm. In this way, good light-emitting characteristics of the red quantum well light-emitting layer 46 are ensured. In addition, the growth temperature of the seventh undoped GaN film layer 461 is the same as that of the InₑGa₁₋ₑN well layer 462, and the growth temperature of the eighth undoped GaN film layer 463 is the same as that of the p-type doped GaN barrier layer 464, which can effectively alleviate the problem of wave shift (offset) under a large current injection.

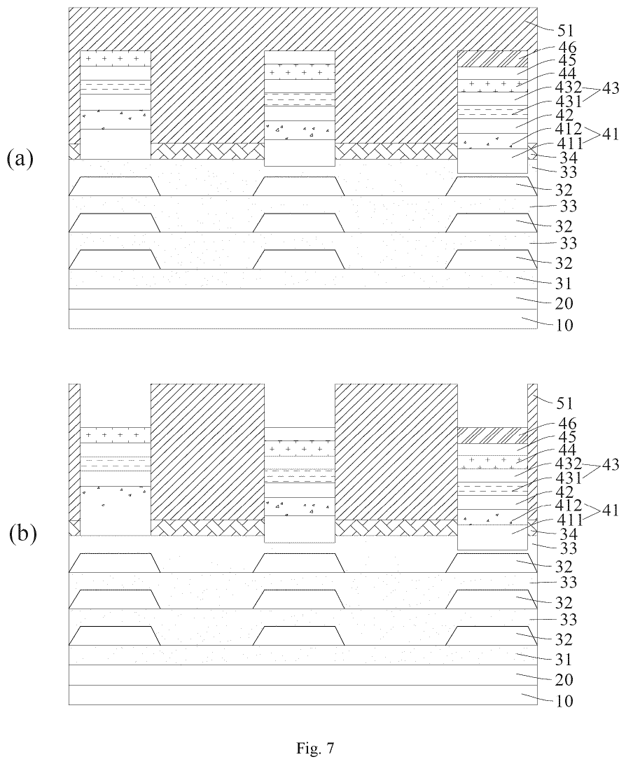

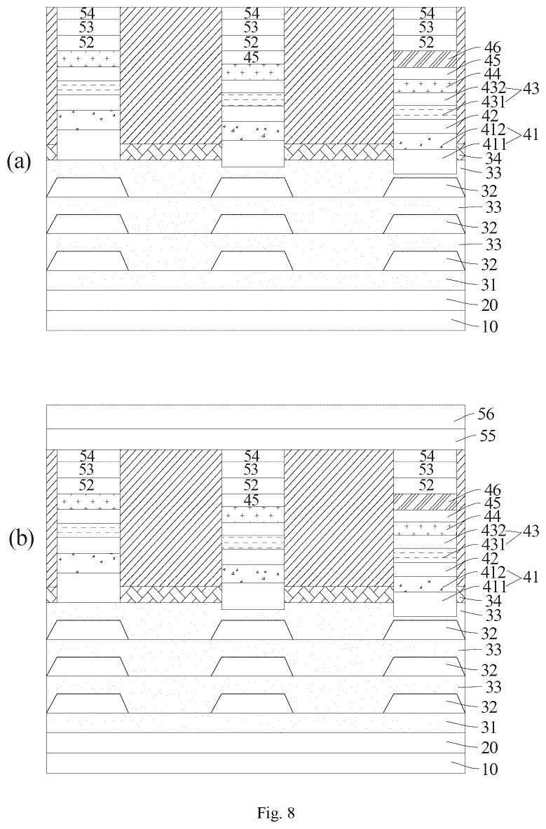

According to an embodiment of the present disclosure, referring to FIG. 7 and FIG. 8, the method for preparing a Micro-LED chip further includes:

S400: depositing a first isolation layer 51 in gaps between the blue pixel column B, the green pixel column G, and the red pixel column R, and the first isolation layer 51 covers surfaces of the blue pixel column B, the green pixel column G, and the red pixel column R, as shown in (a) of FIG. 7. A material of the first isolation layer 51 may be silicon nitride or silicon oxide, and the first isolation layer 51 may be prepared by vapor deposition.

S500: etching and removing parts of the first isolation layer 51 which are on and orthogonally correspond to the surfaces of the blue pixel column B, the green pixel column G, and the red pixel column R to expose the surfaces of the blue pixel column B, the green pixel column G, and the red pixel column R, as shown in (b) of FIG. 7. Specifically, it may be obtained by using a mask and methods such as exposure, development, etching, photoresist stripping, and cleaning. The mask used in this step may be the same as the mask used in the step S6.

S600: growing a protection layer 52, an electron blocking layer 53, and a first partial hole injection layer 54 on the surfaces of the blue pixel column B, the green pixel column G, and the red pixel column R, so that a surface of the first partial hole injection layer 54 away from the substrate is flush with a surface of the first isolation layer 51 away from the substrate, as shown in (a) of FIG. 8. Before growing the protection layer, the product etched in the step S500 is sequentially washed with toluene, acetone, ethanol, and deionized water, dried with nitrogen, and then the protection layer is grown after being heated in a nitrogen atmosphere.

Further, in some embodiments, a sum of the thicknesses of the protection layer 52, the electron blocking layer 53, and the first partial hole injection layer 54 is 120 nm-180 nm, that is, the sum of the thicknesses of the protection layer 52, the electron blocking layer 53, and the first partial hole injection layer 54 is the thickness of the first isolation layer etched in the step S500.

The thickness of the protection layer 52 is 20 nm-40 nm, and the material of the protection layer is undoped gallium nitride. The electron blocking layer 53 includes 4-6 pairs of a p-type doped AlₘGa₁₋ₘN layer and a first p-type doped GaN layer which are arranged in a stacked manner, a hole concentration of the electron blocking layer is 1.5×10¹⁸ cm⁻³-2×10¹⁸ cm⁻³, a thickness of the p-type doped AlₘGa₁₋ₘN layer is 2.5 nm-3.5 nm, an Al component is 20%-30% (that is, m is 0.2-0.3 in AlₘGa₁₋ₘN), and a thickness of the first p-type doped GaN layer is 5 nm-8 nm.

S700: growing a second partial hole injection layer 55 on the surface of the first partial hole injection layer 54 away from the substrate 10 and the surface of the first isolation layer 51 away from the substrate 10, as shown in (b) of FIG. 8. The hole injection layer (including the first partial hole injection layer and the second partial hole injection layer) includes 8-14 pairs of a p-type doped AlₙGa₁₋ₙN layer and a second p-type doped GaN layer which are arranged in a stacked manner, a hole concentration of the electron blocking layer is 1×10¹⁸ cm⁻³-2×10¹⁸ cm⁻³, a thickness of the p-type doped AlₙGa₁₋ₙN layer is 2.5 nm-3.5 nm, an Al component is 10%-20% (that is, n is 0.1-0.2 in AlₙGa₁₋ₙN), and a thickness of the second p-type doped GaN layer is 5 nm-8 nm.

S800: depositing and forming an ohmic contact layer 56 on a surface of the second partial hole injection layer 55 away from the substrate 10, as shown in (b) of FIG. 8. The ohmic contact layer 56 is a p-type heavily doped GaN layer, and a thickness of the ohmic contact layer 56 is 20 nm-40 nm.

After the step S800 is completed, an annealing treatment may be performed on the product after the step S800 in a nitrogen atmosphere to complete the growth of the epitaxial structure.

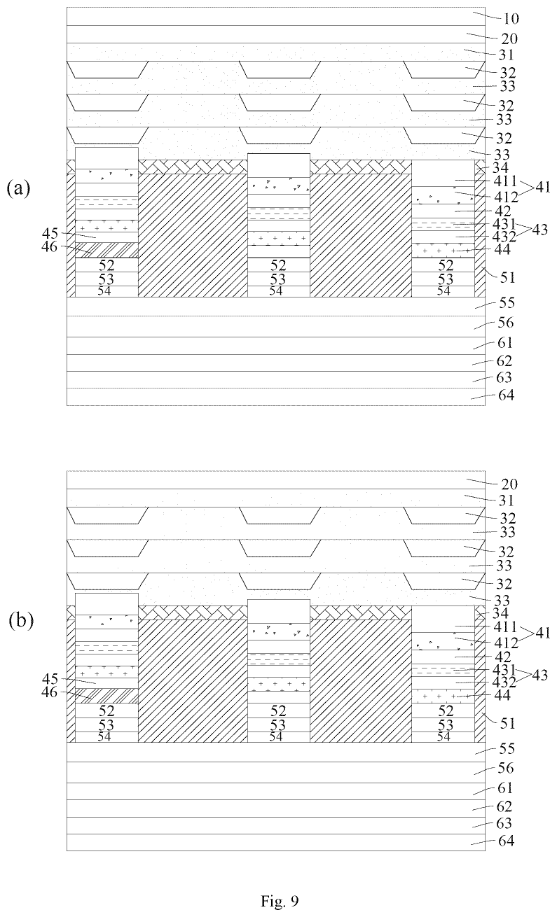

According to an embodiment of the present disclosure, referring to FIG. 9 to FIG. 11, the method for preparing a Micro-LED chip further includes:

S900: sequentially depositing and forming a first conductive film layer 61, a reflector 62, and a bonding metal layer 63 on a surface of the ohmic contact layer 56 away from the substrate 10, as shown in (a) of FIG. 9.

In some embodiments, the first conductive film layer 61 with a thickness of 30 nm-120 nm may be deposited by electron beam evaporation or sputtering (magnetron sputtering), and a rapid annealing process may be further combined to improve the transmittance of the first conductive film layer 61 and reduce the resistance of the first conductive film layer 61. The material of the first conductive film layer may be ITO.

In some embodiments, the reflector 62 with a thickness of 100 nm-300 nm may be deposited by electron beam evaporation or sputtering (magnetron sputtering) to improve the light extraction efficiency of the Micro LED chip. The material of the reflector 62 may be silver or aluminum.

In some embodiments, the bonding metal layer 63 may be deposited by electron beam evaporation or sputtering (magnetron sputtering), and the material thereof includes, but is not limited to, at least one of Cr, Pt, Ni, Ti, Ni, and Ag.

S1000: bonding the pixel driving circuit 64 on a surface of the bonding metal layer 63 away from the substrate 10, as shown in (a) of FIG. 9.

In some embodiments, the bonding metal (materials such as Cr, Pt, Ag, and In) may be deposited on the pixel driving circuit 64 by electron beam evaporation or sputtering (magnetron sputtering), and then the bonding between the bonding metal layer 64 and the pixel driving circuit 64 is completed through the bonding metal.

S1100: peeling the substrate 10, as shown in (b) of FIG. 9.

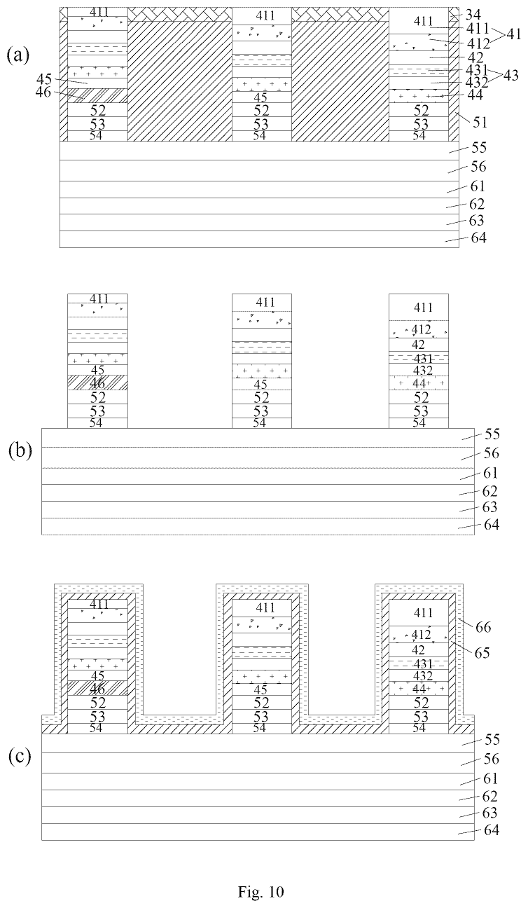

In some embodiments, the substrate is a sapphire substrate, and the substrate 10 may be peeled by a laser lift-off process (LLO) with a laser wavelength of 355 nm, 266 nm, or 248 nm. In other embodiments, the substrate is a silicon substrate, and the substrate 10 may be peeled by a wet etching method. In other embodiments, the substrate is a n-type doped silicon carbide substrate, and the substrate 10 may be peeled by a wet etching method or by inductively coupled plasma etching (ICP-RIE). In other embodiments, the substrate is a n-type doped gallium nitride substrate, and the substrate 10 may be peeled by inductively coupled plasma S1200: etching a layer structure between the pixel columns and the substrate and part of the n-type heavily doped GaN layer 411 in the pixel columns by an etching method (ICP-RIE) until a surface of the blue pixel column B away from the first conductive film layer 61, a surface of the green pixel column G away from the first conductive film layer, and a surface of the red pixel column R away from the first conductive film layer are located in the same plane, as shown in (a) of FIG. 10.

S1300: removing the first passivation isolation layer 51 between the blue pixel column B, the green pixel column G, and the red pixel column R, as shown in (b) of FIG. 10.

In some embodiments, the method for removing the first isolation layer 51 between the blue pixel column B, the green pixel column G, and the red pixel column R may include: removing the first isolation layer (a material of SiNₓ or SiO₂) between the blue pixel column B, the green pixel column G, and the red pixel column R by using an HF solution or a BOE solution (buffered oxide etchant), and washing with deionized water.

S1400: sequentially forming a sidewall passivation layer 65 and a reflective film layer 66 on the surfaces of the pixel columns, as shown in (c) of FIG. 10.

In some embodiments, before the sidewall passivation layer 65 is formed, after the first isolation layer is removed in the step S1300, defects on the sidewalls of the pixel columns are treated by plasma (including hydrogen, oxygen, ammonia, etc.) before film formation using a PECVD device, and then the sidewall passivation layer 65 with a thickness of 60 nm-200 nm is deposited. In addition, the reflective film layer 66 may be grown by sputtering (magnetron sputtering) or atomic layer deposition (ALD) to further improve the light extraction efficiency of the chip. The reflective film layer 66 may be a DBR reflective film layer (distributed Bragg reflector).

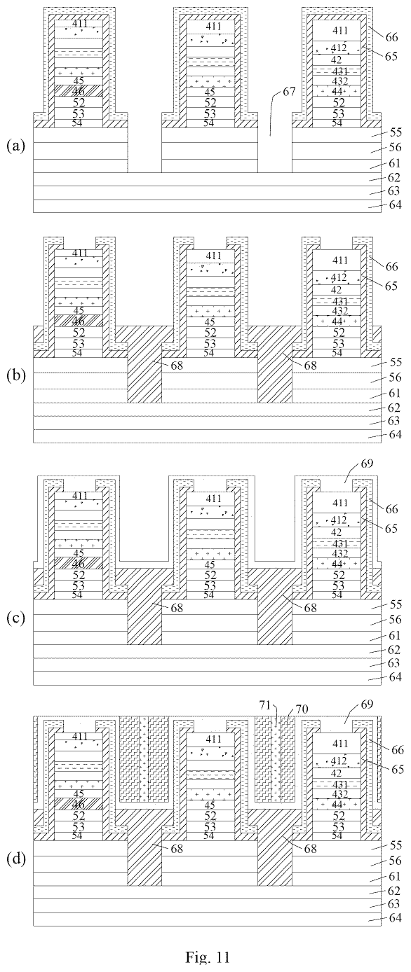

S1500: etching and removing part of the sidewall passivation layer 65, the reflective film layer 66, the second partial hole injection layer 55, the ohmic contact layer 56, and the first conductive film layer 61 between different pixel columns to form an isolation groove 67, as shown in (a) of FIG. 11.

In some embodiments, the isolation groove 67 may be etched by photolithography and ICP-RIE process, and the photoresist stripping and surface cleaning treatment are performed with acetone, ethanol, and deionized water.

S1600: depositing and forming a second isolation layer 68 in the isolation groove 67, as shown in (b) of FIG. 11.

In some embodiments, the second isolation layer 68 may further cover a bottom wall and part of a sidewall of the reflective film layer 66. Specifically, the second isolation layer 68 may be deposited by physical vapor deposition.

S1700: removing at least part of the sidewall passivation layer 65 and the reflective film layer 66 on mesas of the pixel columns to expose the surface of the n-type heavily doped GaN layer 411, as shown in (b) of FIG. 11.

S1800: forming the second conductive film layer 69 on the mesas of the pixel columns, on a sidewall of the reflective film layer 66, and on a surface of the second isolation layer 68, as shown in (c) of FIG. 11.

In some embodiments, the second conductive film layer 69 with a thickness of 30 nm-120 nm may be deposited by magnetron sputtering, and an RTA (rapid annealing) process may be combined to improve the transmittance of the second conductive film layer 69 and reduce the material resistance. The second conductive film layer 69 may be an ITO film layer.

S1900: depositing a third isolation layer 70 on a sidewall and a bottom wall of the second conductive film layer 69, as shown in (d) of FIG. 11, to achieve electrical insulation between the mesas of the pixel columns.

S2000: forming a highly reflective electrode 71 in the third isolation layer 70, and the highly reflective electrode 71 is disposed in contact with the second conductive film layer 69, as shown in (d) of FIG. 11. The highly reflective electrode 71 can reduce optical crosstalk and light emitting divergence angle between the pixels on the one hand, and can improve the light extraction efficiency on the other hand.

In some embodiments, the material of the highly reflective electrode 71 may be aluminum or silver.

According to the embodiments of the present disclosure, the RGB Micro LED pixel columns are monolithically integrated by the epitaxial growth method. On the one hand, monolithic integration can be achieved to realize full color. On the other hand, damage to the sidewalls of the pixel columns from etching in the chip preparation process can be reduced to a certain extent, thereby improving the light-emitting performance of the chip.

In another aspect of the present disclosure, the present disclosure provides a Micro LED chip. According to an embodiment of the present disclosure, the Micro LED chip is prepared by the above method. Therefore, the Micro LED chip can better realize monolithic integration and full color, and further improve the light-emitting performance of the chip. Those skilled in the art can understand that the Micro LED chip has all the features and advantages of the above method for preparing a Micro LED chip, which will not be repeated here.

The terms “first” and “second” used herein are only for the purpose of description, and cannot be understood as indicating or implying relative importance or implicitly indicating the number of indicated technical features. Therefore, the features defined as “first” and “second” may explicitly or implicitly include one or more of the features. In the description of the present application, the meaning of “a plurality” is two or more, unless otherwise specifically defined.

In the description of the present specification, the description with reference to terms “one embodiment”, “some embodiments”, “examples”, “specific examples”, or “some examples”, etc. means that the specific features, structures, materials, or characteristics described in combination with the embodiments or examples are included in at least one embodiment or example of the present disclosure. In the present specification, the schematic representations of the above terms are not necessarily directed to the same embodiments or examples. Moreover, the specific features, structures, materials, or characteristics described may be combined in any one or more embodiments or examples in a suitable manner. Furthermore, those skilled in the art may combine different embodiments or examples described in the present specification and features of different embodiments or examples without contradiction.

Although the embodiments of the present disclosure have been shown and described above, it should be understood that the above embodiments are exemplary and should not be construed as limiting the present disclosure, and those skilled in the art may make changes, modifications, substitutions, and variations to the above embodiments within the scope of the present disclosure.

1. A method for preparing a Micro-LED chip, comprising:
providing a substrate;
forming a buffer layer on a surface of the substrate; and
forming a plurality of pixel columns arranged at intervals on a side of the buffer layer away from the substrate, wherein the pixel columns comprise a blue pixel column, a green pixel column, and a red pixel column, and forming the pixel columns comprises:
epitaxially growing a plurality of first n-type doped GaN layers arranged at intervals on the side of the buffer layer away from the substrate;
growing a first barrier layer on a surface of the first n-type doped GaN layers away from the substrate;
growing a quantum well structure layer on a surface of the first barrier layer away from the substrate;
sequentially growing a blue quantum well light-emitting layer, a green quantum well light-emitting layer, and a red quantum well light-emitting layer on a surface of the quantum well structure layer away from the substrate to obtain the red pixel column;
etching and removing the red quantum well light-emitting layer and the green quantum well light-emitting layer corresponding to a position of the blue pixel column to obtain the blue pixel column; and
etching and removing the red quantum well light-emitting layer corresponding to a position of the green pixel column to obtain the green pixel column.

2. The method according to claim 1, further comprising:
depositing a first isolation layer in gaps between the blue pixel column, the green pixel column, and the red pixel column, wherein the first isolation layer covers surfaces of the blue pixel column, the green pixel column, and the red pixel column;
etching and removing parts of the first isolation layer which are on and orthogonally correspond to the surfaces of the blue pixel column, the green pixel column, and the red pixel column to expose mesas of the blue pixel column, the green pixel column, and the red pixel column;
growing a protection layer, an electron blocking layer, and a first partial hole injection layer on the mesas of the blue pixel column, the green pixel column, and the red pixel column, so that a surface of the first partial hole injection layer away from the substrate is flush with a surface of the first isolation layer away from the substrate;
growing a second partial hole injection layer on the surface of the first partial hole injection layer away from the substrate and the surface of the first isolation layer away from the substrate; and
depositing and forming an ohmic contact layer on a surface of the second partial hole injection layer away from the substrate.

3. The method according to claim 1, further comprising:
S1: growing a first undoped GaN layer on a surface of the buffer layer away from the substrate, wherein a thickness of the first undoped GaN layer is 0.5 μm-1 μm;
S2: forming a first inorganic layer on a surface of the first undoped GaN layer away from the substrate, wherein the first inorganic layer has a plurality of openings arranged at intervals, and a thickness of the first inorganic layer is 10 nm-30 nm;
S3: growing a second undoped GaN layer on a surface of the first undoped GaN layer not covered by the first inorganic layer, wherein the second undoped GaN layer covers a surface of the first inorganic layer, and wherein a thickness of the second undoped GaN layer is 0.5 μm-1 μm; and
S4: repeating steps S2 and S3 until a total thickness of the undoped GaN layers is 3.5 μm-4 μm, wherein an orthographic projection of the pixel columns on the substrate is located within an orthographic projection of the first inorganic layer on the substrate.

4. The method according to claim 3, further comprising:
etching a first groove and a second groove on a surface of the undoped GaN layer away from the substrate, wherein an orthographic projection of the first groove on the substrate overlaps with an orthographic projection of the green pixel column on the substrate, wherein an orthographic projection of the second groove on the substrate overlaps with an orthographic projection of the red pixel column on the substrate, and a depth of the second groove is greater than a depth of the first groove; and
depositing a second inorganic layer on the surface of the undoped GaN layer away from the substrate, wherein the second inorganic layer has a first through hole, a second through hole, and a third through hole penetrating through the second inorganic layer, the first through hole exposes the first groove, the second through hole exposes the second groove, and the third through hole exposes a predetermined region of the undoped GaN layer, wherein an orthographic projection of the predetermined region on the substrate overlaps with an orthographic projection of the blue pixel column on the substrate,
wherein the blue pixel column is disposed in the third through hole, the green pixel column is disposed in the first through hole, and the red pixel column is disposed in the second through hole.

5. The method according to claim 4, wherein the depth of the first groove is 28 nm-145 nm, and the depth of the second groove is 50 nm-300 nm; and
optionally, the thickness of the second inorganic layer is 100 nm-300 nm.

6. The method according to claim 1, wherein a growing the first n-type doped GaN layer comprises sequentially growing a n-type heavily doped GaN layer and a n-type lightly doped GaN layer, a doping concentration of the n-type heavily doped GaN layer is 5×10¹⁸ cm⁻³-1×10¹⁹ cm⁻³, a thickness of the n-type heavily doped GaN layer is 1.5 μm-2.5 μm, a doping concentration of the n-type lightly doped GaN layer is 3×10¹⁷ cm⁻³-6×10¹⁷ cm⁻³, and a thickness of the n-type lightly doped GaN layer is 0.3 μm-0.5 μm;
the first barrier layer is undoped GaN, and a thickness of the first barrier layer is 20 nm-60 nm;
growing the quantum well structure layer comprises sequentially growing a first quantum well structure layer and a second quantum well structure layer, the first quantum well structure layer comprises an InₓGa₁₋ₓN well layer and a GaN barrier layer which are arranged in a stacked manner, x is 0.01-0.03, a thickness of the InₓGa₁₋ₓN well layer is 2.5 nm-3.5 nm, and a thickness of the GaN barrier layer is 5 nm-15 nm; and
the second quantum well structure layer comprises an In_{y}Ga_{1-y}N well layer and a second n-type doped GaN barrier layer which are arranged in a stacked manner, y is 0.03-0.05, a thickness of the In_{y}Ga_{1-y}N well layer is 2.5 nm-3.5 nm, a thickness of the second n-type doped GaN barrier layer is 5 nm-15 nm, and a doping concentration of the second n-type doped GaN barrier layer is 1×10¹⁷ cm⁻³-5×10¹⁷ cm⁻³.

7. The method according to claim 1, wherein the blue quantum well light-emitting layer comprises a first undoped GaN film layer, an InₐGa₁₋ₐN well layer, a second undoped GaN film layer, and an In_{b}Ga_{1-b}N barrier layer which are arranged in a stacked manner, wherein a is 0.18-0.21, and b is 0.01-0.05;
the green quantum well light-emitting layer comprises a third undoped GaN film layer, an In_{c}Ga_{1-c}N well layer, a fourth undoped GaN film layer, a first n-type doped GaN barrier layer, a fifth undoped GaN film layer, an In_{d}Ga_{1-d}N well layer, a sixth undoped GaN film layer, and a second n-type doped GaN barrier layer which are arranged in a stacked manner, wherein c is 0.24-0.25, and d is 0.25-0.28; and
the red quantum well light-emitting layer comprises a seventh undoped GaN film layer, an InₑGa₁₋ₑN well layer, an eighth undoped GaN film layer, a p-type doped GaN barrier layer, and an AlₕGa₁₋ₕN layer which are arranged in a stacked manner, wherein e is 0.35-0.38, and h is 0.10-0.30.

8. The method according to claim 7, wherein the blue quantum well light-emitting layer, the green quantum well light-emitting layer and the red quantum well light-emitting layer further satisfy at least one of the following conditions:
thicknesses of the first undoped GaN film layer to the eighth undoped GaN film layer are 12 nm-8 nm, respectively;
a thickness of the InₐGa₁₋ₐN well layer is 2.5 nm-3.5 nm, and a thickness of the In_{b}Ga_{1-b}N barrier layer is 5 nm-15 nm;
a thickness of the In_{c}Ga_{1-c}N well layer is 2.5 nm-3.5 nm, a thickness of the first n-type doped GaN barrier layer is 5 nm-15 nm, a doping concentration of the first n-type doped GaN barrier layer is 1×10¹⁷ cm⁻³-5×10¹⁷ cm⁻³, a thickness of the In_{d}Ga_{1-d}N well layer is 2.5 nm-3.5 nm, a thickness of the second n-type doped GaN barrier layer is 5 nm-15 nm, and a doping concentration of the second n-type doped GaN barrier layer is 1×10¹⁷ cm⁻³-5×10¹⁷ cm⁻³; and
a thickness of the InₑGa₁₋ₑN well layer is 2.5 nm-3.5 nm, a thickness of the p-type doped GaN barrier layer is 5 nm-15 nm, and a thickness of the AlₕGa₁₋ₕN layer is 1 nm-2 nm.

9. The method according to claim 2, wherein a sum of thicknesses of the protection layer, the electron blocking layer, and the first partial hole injection layer is 120 nm-180 nm.

10. The method according to claim 3, wherein the substrate is a sapphire substrate, and the buffer layer is an aluminum nitride layer; or
the substrate is a silicon substrate, the buffer layer is an aluminum nitride layer and an aluminum gallium nitride layer, and the aluminum content in the aluminum gallium nitride layer decreases gradually in a direction away from the substrate; or
the substrate is a n-type doped silicon carbide substrate, the buffer layer is an aluminum nitride layer and an aluminum gallium nitride layer, and the aluminum content in the aluminum gallium nitride layer decreases gradually in a direction away from the substrate.

11. The method according to claim wherein the substrate is a n-type doped silicon carbide substrate, the buffer layer is a n-type doped aluminum gallium nitride layer, and the pixel columns are directly formed on a surface of the buffer layer away from the substrate; or
the substrate is a n-type doped gallium nitride substrate, the buffer layer is an aluminum nitride layer, and the pixel columns are directly formed on a surface of the buffer layer away from the substrate.

12. The method according to claim 2, further comprising:
sequentially depositing and forming a first conductive film layer, a reflector, and a bonding metal layer on a surface of the ohmic contact layer away from the substrate;
bonding a pixel driving circuit on a surface of the bonding metal layer away from the substrate;
peeling the substrate;
etching a layer structure between the pixel columns and the substrate and part of the first n-type doped GaN layer in the pixel columns by an etching method until a surface of the blue pixel column away from the first conductive film layer, a surface of the green pixel column away from the first conductive film layer, and a surface of the red pixel column away from the first conductive film layer are located in the same plane;
removing the first isolation layer between the blue pixel column, the green pixel column, and the red pixel column;
sequentially forming a sidewall passivation layer and a reflective film layer on the surfaces of the pixel columns;
etching and removing part of the sidewall passivation layer, the reflective film layer, the second partial hole injection layer, the ohmic contact layer, and the first conductive film layer between different pixel columns to form an isolation groove;
depositing and forming a second isolation layer in the isolation groove;
removing at least part of the sidewall passivation layer and the reflective film layer on the mesas of the pixel columns to expose a surface of the first n-type doped GaN layer;
forming a second conductive film layer on the mesas of the pixel columns, on a sidewall of the reflective film layer, and on a surface of the second isolation layer;
depositing a third isolation layer on a sidewall and a bottom wall of the second conductive film layer; and
forming a highly reflective electrode in the third isolation layer, and the highly reflective electrode is disposed in contact with the second conductive film layer.

13. A Micro LED chip, which is prepared by the a method comprising:
providing a substrate;
forming a buffer layer on a surface of the substrate; and
forming a plurality of pixel columns arranged at intervals on a side of the buffer layer away from the substrate, wherein the pixel columns comprise a blue pixel column, a green pixel column, and a red pixel column, and forming the pixel columns comprises:
epitaxially growing a plurality of first n-type doped GaN layers arranged at intervals on the side of the buffer layer away from the substrate;
growing a first barrier layer on a surface of the first n-type doped GaN layers away from the substrate;
growing a quantum well structure layer on a surface of the first barrier layer away from the substrate;
sequentially growing a blue quantum well light-emitting layer, a green quantum well light-emitting layer, and a red quantum well light-emitting layer on a surface of the quantum well structure layer away from the substrate to obtain the red pixel column;
etching and removing the red quantum well light-emitting layer and the green quantum well light-emitting layer corresponding to a position of the blue pixel column to obtain the blue pixel column; and
etching and removing the red quantum well light-emitting layer corresponding to a position of the green pixel column to obtain the green pixel column.

14. A Micro LED chip, which is prepared by the method according to claim 2.

15. A Micro LED chip, which is prepared by the method according to claim 3.

16. A Micro LED chip, which is prepared by the method according to claim 4.

17. A Micro LED chip, which is prepared by the method according to claim 5.

18. A Micro LED chip, which is prepared by the method according to claim 6.

19. A Micro LED chip, which is prepared by the method according to claim 7.

20. A Micro LED chip, which is prepared by the method according to claim 8.
